(19) United States
(12) Patent Application Publication
(10) Pub. No.: US 2023/0027886 A1
(43) Pub. Date: Jan. 26, 2023

(54) SYSTEMS AND METHODS FOR FABRICATING CRYSTALS OF METAL COMPOUNDS

(71) Applicants: Hongjie Qiu, Milpitas, CA (US); Dong Rick Qiu, Milpitas, CA (US)

(72) Inventors: Hongjie Qiu, Milpitas, CA (US); Dong Rick Qiu, Milpitas, CA (US)

(21) Appl. No.: 17/869,710

(22) Filed: Jul. 20, 2022

Related U.S. Application Data
(60) Provisional application No. 63/223,731, filed on Jul. 20, 2021.

(51) Int. Cl. C30B 1/00; C30B 29/40; C30B 29/36; B22F 9/08

(52) U.S. Cl. CPC C30B 1/00; C30B 29/406; C30B 29/36; B22F 9/082; B22F 2009/0836; B22F 2301/052; B22F 2301/30

(57) ABSTRACT

The present disclosure provides systems and methods for forming block crystals of a metal compound. In some embodiments, a method for forming block crystals of a metal compound may comprise (a) introducing a source metal into a furnace; (b) forming a complete or partial vacuum in the furnace and increasing a temperature of the furnace above a melting point of the source metal to form a liquid flow of the source metal; (c) breaking the liquid flow to generate particles of the source metal; (d) ionizing the particles in an ionization chamber to form ionized particles, wherein the ionization chamber has a temperature above a decomposition temperature of the metal compound; and (e) introducing the ionized particles into a growth chamber comprising a reactive gas that is reactive with the ionized particles, to thereby form the block crystals of the metal compound.

### CROSS-REFERENCE

This application claims the benefit of U.S. Provisional Application No. 63/223,731, filed Jul. 20, 2021, which application is entirely incorporated herein by reference.

### BACKGROUND

Gallium nitride (GaN) is a high-intensity luminescent material that is resistant to high temperature, high pressure, and radiation. It is also non-toxic and pollutant-free. Due to its wide bandgap, GaN-based semiconductor materials have the highest photoelectric conversion efficiency among photovoltaic materials. High-purity GaN is also an important raw material for manufacturing high-end semiconductor device and substrates. Compared to silicon carbide and alumina, GaN has superior lattice matching and material consistency.

In general, GaN crystals are formed using a vapor phase method or a liquid phase method. The precursor materials used in these methods are gallium intermediate or gallium compound materials; when the gallium intermediate or gallium compound materials are made, a large number of toxic solutions and solvents are used, resulting in the final GaN single crystal blocks containing many impurities and parasitic reaction products. At the same time, these commonly-used methods have lower efficiency (i.e., lower epitaxial growth rate—100 to 300 micrometers per hour for hydride vapor phase epitaxy (HPVE); 10 to 80 micrometers per hour of ammonothermal method; 20 micrometers per hour for high-pressure solution growth (HPSG); 50 micrometers per hour for sodium flux method).

### SUMMARY

The present disclosure provides systems and methods for fabricating gallium nitride (GaN) crystals and other metal compound crystals without the use of solvents and catalysts by using physical methods to convert solid metals into ultra-fine particles and to nucleate and crystallize such particles into crystals. Because no toxic solutions or solvents are used, the resulting crystals have fewer impurities and parasitic reaction products.

An aspect of the present disclosure provides a method for forming block crystals of a metal compound, comprising: (a) introducing a source metal into a furnace; (b) forming a complete or partial vacuum in the furnace and increasing a temperature of the furnace above a melting point of the source metal to form a liquid flow of the source metal; (c) breaking the liquid flow to generate particles of the source metal; (d) ionizing the particles in an ionization chamber to form ionized particles, a temperature of the ionization chamber is above a decomposition temperature of the metal compound; and (e) introducing the ionized particles into a growth chamber comprising a reactive gas that is reactive with the ionized particles, thereby forming the block crystals of the metal compound.

In some embodiments, (c) comprises one or more of (1) applying a high-pressure gas to the liquid flow, (2) applying ultrasonic waves to the liquid flow, or (3) mechanically vibrating the liquid flow. In some embodiments, (c) comprises (1) applying a high-pressure gas to the liquid flow, and (2) applying ultrasonic waves to the liquid flow. In some embodiments, (c) comprises (1) applying a high-pressure gas to the liquid flow, and (2) mechanically vibrating the liquid flow. In some embodiments, (c) comprises (1) applying a high-pressure gas to the liquid flow, (2) applying ultrasonic waves to the liquid flow, and (3) mechanically vibrating the liquid flow. In some embodiments, (d) comprises introducing a flow of another inert gas into the ionization chamber, thereby preventing (1) aggregation of the ionized particles and (2) adhesion of the ionized particles to the ionization chamber. In some embodiments, (b) comprises, subsequent to forming the complete or partial vacuum in the furnace, introducing another inert gas into the furnace. In some embodiments, each of said high-pressure gas, the inert gas and the another inert gas is independently helium, nitrogen or argon. In some embodiments, subsequent to (c), removing a subset of the particles that are larger than a threshold size before reaching the ionization chamber. In some embodiments, the subset of the particles are reused. In some embodiments, (c) comprises atomizing and vaporizing the liquid flow. In some embodiments, (c) is performed without a solvent.

In some embodiments, the ionized particles diffuse from the ionization chamber to the growth chamber along a concentration gradient or a temperature gradient. In some embodiments, the block crystals of the metal compound form in a sedimentary groove in a bottom of the growth chamber. In some embodiments, a temperature of the growth chamber facilitates growth of the block crystals of the metal compound. In some embodiments, the reactive gas is catalyst-free. In some embodiments, the source metal is a pure metal. In some embodiments, the source metal is a combination of metals. In some embodiments, (b) comprises increasing the temperature of the furnace above a melting point of a metal with a highest melting point in the combination of metals. In some embodiments, the source metal is gallium, aluminum, indium, silicon, or a combination thereof. In some embodiments, the source metal is gallium, the reactive gas is nitrogen or ammonia, and the metal compound is gallium nitride. In some embodiments, the source metal is aluminum, the reactive gas is nitrogen or ammonia, and the metal compound is aluminum nitride. In some embodiments, the source metal is silicon, the reactive gas is methane, and the metal compound is silicon carbide. In some embodiments, the source metal is indium, the reactive gas is nitrogen or ammonia, and the metal compound is indium nitride.

Another aspect of the present disclosure provides an apparatus for forming block crystals of a metal compound, comprising: a furnace configured to heat a source metal to form a liquid flow of the source metal; a fragmentation device coupled to the furnace, wherein the fragmentation device is configured to generate particles of the source metal from the liquid flow; an ionization chamber coupled to the fragmentation device, wherein the ionization chamber is configured to ionize the particles to form ionized particles; and a growth chamber coupled to the ionization chamber, wherein the growth chamber is configured to facilitate growth of the block crystals of the metal compound through a reaction between the ionized particles and a reactive gas in the growth chamber.

In some embodiments, the fragmentation device comprises one or more atomization devices and a vaporization device. In some embodiments, the one or more atomization devices comprise a gas atomizer, a mechanical vibrator, or an ultrasonic atomizer. In some embodiments, the apparatus further comprises a particle selector disposed between said one or more atomization devices and said vaporization device. In some embodiments, the particle selector comprises a first plurality of inclined gas holes. In some embodiments, the fragmentation device comprises one or more atomization devices and a vaporization device; and the apparatus further comprises a particle selector disposed between the one or more atomization devices and the vaporization device. In some embodiments, the one or more atomization devices comprise a gas atomizer, a mechanical vibrator, or an ultrasonic atomizer. In some embodiments, the apparatus comprises an ion selector disposed between said ionization chamber and said growth chamber. In some embodiments, the particle selector comprises a second plurality of inclined gas holes. In some embodiments, the ionization chamber comprises a particle rotation-suspension setting disposed on a bottom portion of the ionization chamber, the particle rotation-suspension setting is configured to generate a plurality of upward inert gas flows introduced by a plurality of straight holes and a plurality of inclined inert gas flows introduced by a third plurality of inclined holes. In some embodiments, the plurality straight holes and said third plurality of inclined holes (1) are distributed substantially in a circular shape or an irregularly shape, (2) are crossed with each other or in substantially alternate pattern, or (3) are substantially evenly distributed at said bottom of said ion chamber. In some embodiments, the furnace comprises a crucible configured to hold the source metal. In some embodiments, the crucible is sealed. In some embodiments, the crucible is open to the furnace. In some embodiments, the furnace comprises a vacuuming channel configured to remove air from the crucible or the furnace, or both, to form a full or partial vacuum in the crucible or the furnace. In some embodiments, the furnace comprises a gas channel configured to supply an inert gas to the crucible or the furnace, or both. In some embodiments, the vacuuming channel or the gas channel are disposed in a top portion of the crucible or a top portion of the furnace. In some embodiments, the apparatus further comprises a diversion channel that couples the furnace to the fragmentation device. In some embodiments, the one or more atomization devices and the vaporization device are connected in series or integrated together. In some embodiments, the one or more atomization devices are a plurality of atomization devices, and the plurality of atomization devices are connected in series or integrated together. In some embodiments, the one or more atomization devices comprise a gas atomizer, a mechanical vibrator, or an ultrasonic atomizer. In some embodiments, the vaporization device comprises an induction heater, direct current arc, a plasma source, a microwave source, or a laser. In some embodiments, the growth chamber comprises a deposition-growth room. In some embodiments, the deposition-growth room comprises a top ion diffusion zone, a bottom growth zone, and an isolation grid disposed between the ion diffusion zone and the growth zone. In some embodiments, the isolation grid comprises a plurality of holes that allow diffusion of the ionized particles. In some embodiments, the bottom growth zone comprises circular sedimentary grooves for growing the block crystals of the metal compound. In some embodiments, the fragmentation device is coupled to a bottom portion of the furnace, wherein the ionization chamber is coupled to a side of the fragmentation device, and wherein the growth chamber is coupled to a top of the ionization chamber. In some embodiments, the ionization chamber comprises a discharge port for coarse particles, wherein the discharge port is disposed in a bottom portion of the ionization chamber. In some embodiments, the growth chamber comprises a deposition-growth room, wherein the deposition-growth room comprises a top gas accumulation zone, a middle ion diffusion zone, a bottom growth zone, a first isolation grid disposed between the middle ion diffusion zone and the bottom growth zone, and a second isolation grid disposed between the top gas accumulation zone and the middle ion diffusion zone. In some embodiments, an entrance to the deposition-growth room is in the middle ion diffusion zone. In some embodiments, the top gas accumulation zone comprises an excess gas discharge port.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 is a flow chart of a process for producing block crystals of metal compounds, according to some embodiments of the present disclosure;

FIG. 2 schematically illustrates a smelting furnace, according to some embodiments of the present disclosure;

FIG. 3 schematically illustrates an alternative embodiment of the smelting furnace;

FIG. 4 schematically illustrates a first fragmentation device, according to some embodiments of the present disclosure;

FIG. 5 schematically illustrates a second embodiment of a fragmentation device;

FIG. 6 schematically illustrates a third embodiment of a fragmentation device;

FIG. 7 schematically illustrates an ionization chamber for generating ionized particles, according to some embodiments of the present disclosure;

FIG. 8 schematically illustrates a second embodiment of an ionization chamber for generating ionized particles;

FIG. 9 schematically illustrates a third embodiment of an ionization chamber for generating ionized particles;

FIG. 10 schematically illustrates a fourth embodiment of an ionization chamber for generating ionized particles;

FIG. 11 schematically illustrates a fifth embodiment of an ionization chamber for generating ionized particles;

FIG. 12 schematically illustrates a sixth embodiment of an ionization chamber for generating ionized particles;

FIG. 13 schematically illustrates a seventh embodiment of an ionization chamber for generating ionized particles;

FIG. 14 schematically illustrates a growth chamber for producing block crystals of metal compounds, according to some embodiments of the present disclosure;

FIG. 15 schematically illustrates a second embodiment of a growth chamber for producing block crystals of metal compounds;

FIG. 16 schematically illustrates a vertical apparatus for producing block crystals of a compound, according to some embodiments of the present disclosure;

FIG. 17 schematically illustrates the smelting furnace of the apparatus of FIG. 16, according to some embodiments of the present disclosure;

FIG. 18 schematically illustrates the fragmentation device of the apparatus of FIG. 16, according to some embodiments of the present disclosure;

FIG. 19 schematically illustrates the ionization chamber of the apparatus of FIG. 16, according to some embodiments of the present disclosure;

FIG. 20 schematically illustrates the growth chamber of the apparatus of FIG. 16, according to some embodiments of the present disclosure;

FIG. 21 is a flow chart of a process for producing gallium nitride block crystals, according to some embodiments of the present disclosure;

FIG. 22 schematically illustrates a horizontal apparatus for producing block crystals of a compound, according to some embodiments of the present disclosure;

FIG. 23 schematically illustrates of the smelting furnace of the apparatus of FIG. 22, according to some embodiments of the present disclosure;

FIG. 24 schematically illustrates the fragmentation device of the apparatus of FIG. 22, according to some embodiments of the present disclosure;

FIG. 25 schematically illustrates the ionization chamber of the apparatus of FIG. 22, according to some embodiments of the present disclosure.;

FIG. 26 schematically illustrates the growth chamber of the apparatus of FIG. 22, according to some embodiments of the present disclosure; and

FIG. 27 is a flow chart of a process for producing silicon carbide block crystals, according to some embodiments of the present disclosure.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

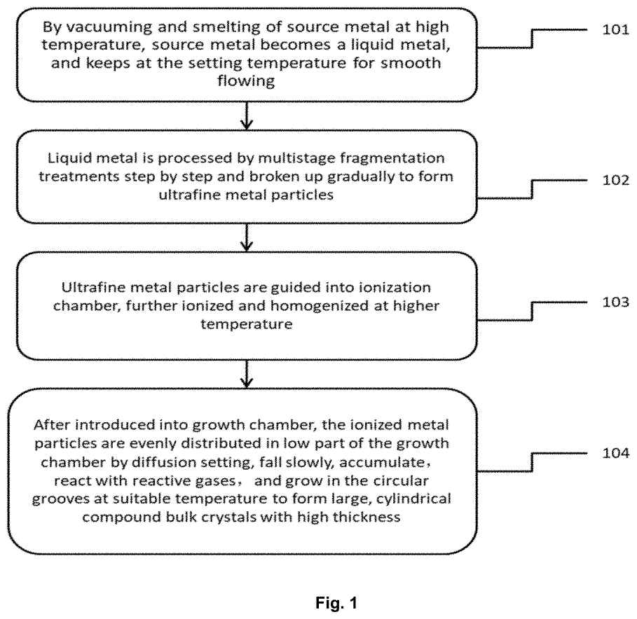

FIG. 1 is a flow chart of a process for producing block crystals of metal compounds, according to some embodiments of the present disclosure. In an operation 101, a source metal is placed into a high temperature container. Air from the container may be evacuated to form a full or partial vacuum. The source metal may then be heated to a liquid state and maintained at a particular temperature to facilitate a smooth flow. In some case, after evacuation of air from the container, the container may be filled with inert gas so as to prevent contamination of the liquid metal (e.g., with air or other impurities). The inert gas may be helium, nitrogen, argon, or the like.

The source metal may be a metal with high purity, such as gallium, aluminum, silicon, or a combination of thereof. The temperature of the container may be greater than the melting point of the source metal when the source metal is a single, pure metal; if the source metal is a combination of metals, the temperature of the container may be greater than the melting point of the metal in the combination of metals with the highest melting point.

The high-temperature container may be open and located at the center of the bottom of a smelting furnace with the top of the smelting furnace sealing the container from an external environment; alternatively, the high temperature container may have its own seal.

In an operation 102, the liquid metal is made to become a narrow liquid metal flow. The narrow liquid metal flow is then fragmented in a multistage process to generate fine or ultrafine (nanoscale) metal particles that are solvent-free. The multistage fragmentation may comprise atomization and vaporization of the liquid metal flow. The atomization and vaporization can be performed separately, in series, or in a single integrated step.

The atomization may be performed using a high-pressure gas, mechanical vibrator with a certain frequency, or an ultrasonic atomizer. The atomization may be performed by a single device, by multiple devices in series, or by multiple devices operating together. Generally, gas atomization can create particles with an average particle size of 30-50 μm. Ultrasonic atomization may create particles with an average particle size of 10-20 μm. Also, both can generate particles with the smaller size of 100-500 nm at 0.4-0.6 kg/h, which takes less than 2-3% of the total weight. The vaporization may be performed using an induction heater, direct current arc vaporizer, a microwave source, a plasma source, or laser vaporizer. Vaporization results in vaporized micro and micro-nano metal particles under high temperature. The vaporization device (such as plasma with a temperature of more than 10,000° C.) may only work on the metal particles with a size of less than 10 μm and break them into particles with a 10-100 nm size. Otherwise, it may not break them at all and result in hard shells from surface reactions, which can be difficult to break. However, the cost of plasma is high.

In an operation 103, the ultrafine metal particles are guided into an ionization chamber. The temperature of the ionization chamber is set above the decomposition temperature of the metal to facilitate further ionization of the ultrafine particles. Meanwhile, due the high temperature, the formation of metal compounds (polycrystals) in the ionization chamber is avoided or reduced.

In an operation 103, an inert gas (e.g., helium, nitrogen or argon) is introduced to mix and stir with the ionized metal particles so that the particles are homogenized; the inert gas is made to rotate, blow, and sweep along the inner wall of the ionization chamber so as to avoid or reduce the adhesion of particles on the inner wall. The ionized metal particles, which are driven by the inert gas, collide with each other and become smaller so that more ionized metal particles are generated. The aggregation and accumulation of ionized metal particles in the ionization chamber is minimized by the continuous moving of the particles.

In an operation 104, the ionized metal particles diffuse from the ionization chamber, which has a high concentration of particles at a high temperature, to the growth chamber, which has a lower concentration of particles at a lower temperature. After diffusion, the ionized metal particles are distributed uniformly in the lower part of the growth chamber, fall slowly, accumulate, react with a catalyst-free reactive gas, and grow in a circular groove at suitable temperature to become large, cylindrical metal compound block crystals in the bottom of the growth chamber.

The apparatus and method described in this disclosure can be adapted to produce many different types of block crystals by adjusting the reaction species, melting temperature, and environments in the ionization chamber and growth chamber. Examples of block crystals produced with this method are nitrides, oxides, and carbides of metals, and the like.

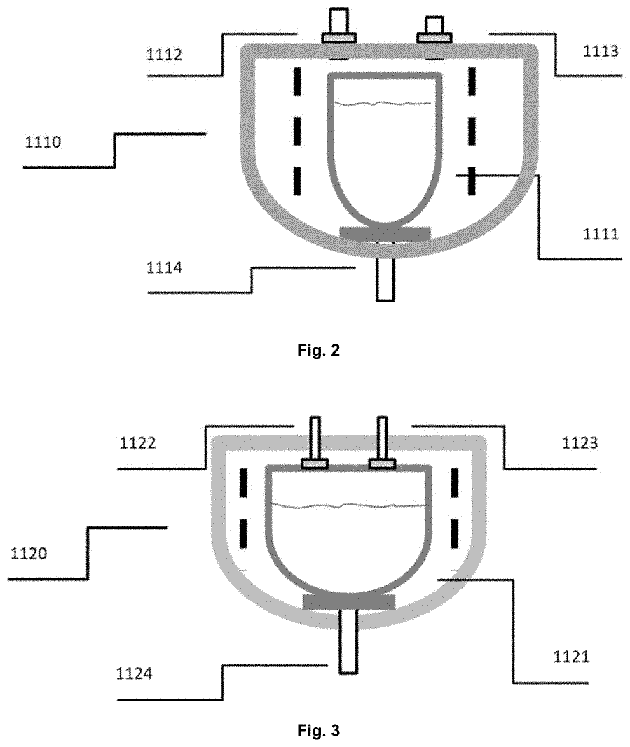

FIG. 2 schematically illustrates a smelting furnace 1110, according to some embodiments of the present disclosure. The smelting furnace 1110 includes a vacuum crucible/container 1111 for holding the source metal, a vacuuming channel 1112, a gas channel 1113, and a diversion pipe 1114 for the narrow liquid metal flow. The vacuum crucible/container 1111 is open on top. The vacuuming channel 1112 and gas channel 1113 are located on the top of the smelting furnace 1110. The vacuuming channel 1112 can use negative pressure to remove air from the vacuum crucible/container 1111 to generate a full or partial vacuum. The gas channel 1113 can introduce an inert gas into the vacuum crucible/container 1111. The diversion pipe 1114 is connected to the bottom of the vacuum crucible/container 1111. The opposite end of the diversion pipe 1114 may be connected to the fragmentation device.

FIG. 3 schematically illustrates an alternative embodiment of the smelting furnace. The smelting furnace 1120 of FIG. 3 includes a vacuum crucible/container 1121 for holding the source metal, a vacuuming channel 1122, a gas channel 1123, and a diversion pipe 1124 for the narrow liquid metal flow. The vacuum crucible/container 1111 is sealed on top. The vacuuming channel 1122 and gas channel 1123 are located on the top of the vacuum crucible/container 1121; the diversion pipe 1124 is connected to the bottom of the vacuum crucible/container 1121. The opposite end of the diversion pipe 1124 may be connected to the fragmentation device.

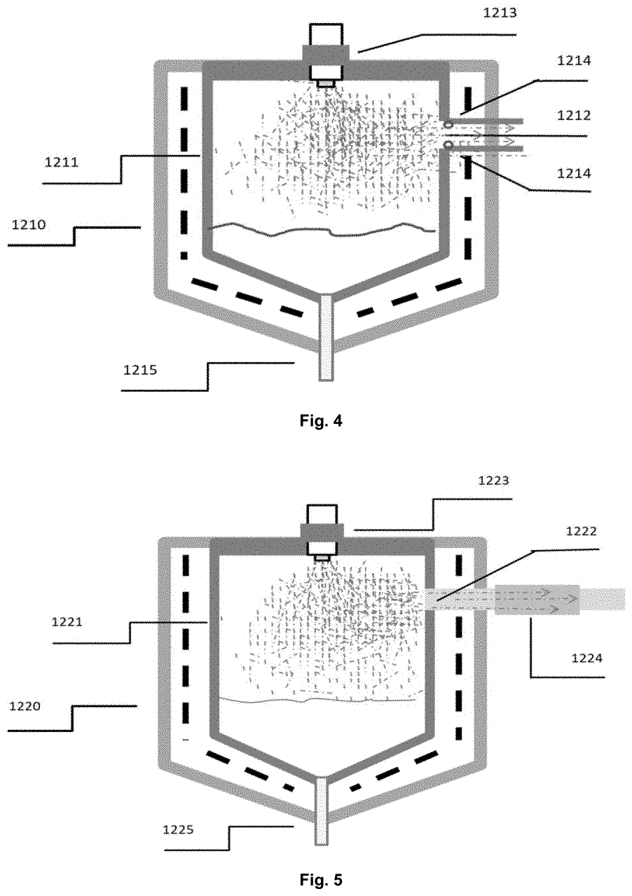

FIG. 4 schematically illustrates a first fragmentation device 1210, according to some embodiments of the present disclosure. The first fragmentation device 1210 includes a collection tank 1211, an outlet 1212 for ultrafine metal particles, an atomization device 1213, a particle selector 1214, and a discharge port 1215 for coarse droplets. The particle selector 1214 may be configured to allows particles of a certain size to pass through it (e.g., not more than about 500 nm for at least 85% of the particles that pass through the particle selector 1214). In some embodiments, the particles distributed in the first fragmentation device such that the smaller (and lighter) particles may mainly stay (or suspend) at the upper portion of the first fragmentation device 1210 while the bigger (and heavier) particles may mainly stay (or suspend) at the lower portion of the first fragmentation device 1210. In some embodiment, the particle selector 1214 applies a pressure differential between at least the bulk of the first fragmentation device 1210 and the outlet 1212 around the entrance of the outlet 1212 such that particles with pre-determined particle sizes are allowed to pass through the particle selector 1214 and enter the outlet 1212. In some embodiments, the pressure differential and/or the location of the particle selector 1214 (e.g., there may be a plurality of outlet 1212 and its corresponding particle selector 1214 distributed vertically along the side wall of the first fragmentation device; or different first fragmentation device 1210 may have different positions for the outlet 1212 and its corresponding particle selector 1214 relative to the bottom of the first fragmentation device 1210) can be adjusted to allow different size range of the particle to pass through the particle selector 1214. In some embodiments, the particle selector may comprise a plurality of inclined gas holes whose orientation can inject inert gas along the passage of the outlet 1212 and away from the first fragmentation device 1210. In some embodiments, the plurality of inclined holes may point away from the fragmentation device. In some embodiments, the momentum caused by the injected inert gas through the plurality of inclined holes create the pressure differential such that particles of predetermined sizes may be pushed into the outlet 1212. In some embodiments, the plurality of holes may be connected with an inert gas source. In some embodiments, the particle selector 1214 is configured to select particles whose sizes are no more than about 1, 5, 10, 20, 30, 40, 50, 60, 70, 80, 90, 100, 150, 200, 250, 300, 350, 400, 450, or 500 nm. In some embodiments, for each of the selected range of particle sizes, the particles having the selected range of particle size are at least 50%, 55%, 60%, 65%, 70%, 75%, 80%, 85%, 90%, 95% of the particles that pass through the particle selector 1214. Particles that are too large to pass through the particle selector 1214 may eventually fall to the bottom of the first fragmentation device 1210 and pass through the discharge port 1215. Such particles may be reused later. The outlet 1212 is located on the side of the collection tank 1211; the atomization device 1213 is located at the top of the collection tank 1211; the particle selector 1214 is located or embedded on the inner wall of the outlet 1212; and the discharge port 1215 for coarse metal droplets is located on the bottom of the collection tank 1211.

FIG. 5 schematically illustrates a second embodiment of a fragmentation device 1220. The second fragmentation device 1220 includes a collection tank 1221, an outlet 1222 for micro-nano metal particles, an atomization device 1223, a vaporization device 1224, and a discharge port 1225 for coarse metal droplets. The outlet 1222 for micro-nano metal particles is located on the side of the collection tank 1221 of metal liquid; the atomization device 1223 is located at the top of the collection tank 1221; the vaporization device 1224 is connected to the outlet 1222 for the micro-nano metal particles; and the discharge port 1225 for coarse metal droplets is located on the bottom of the collection tank 1221 of metal liquid. The atomization device may be used first. Then particles with a size of less than 10 μm may be selected for vaporization, with coarser particles left for re-atomization. Last, the smaller selected particles may be guided to the vaporization device by the pressure difference between collection tank and vaporization device for further breaking into nanometer or atomic particles.

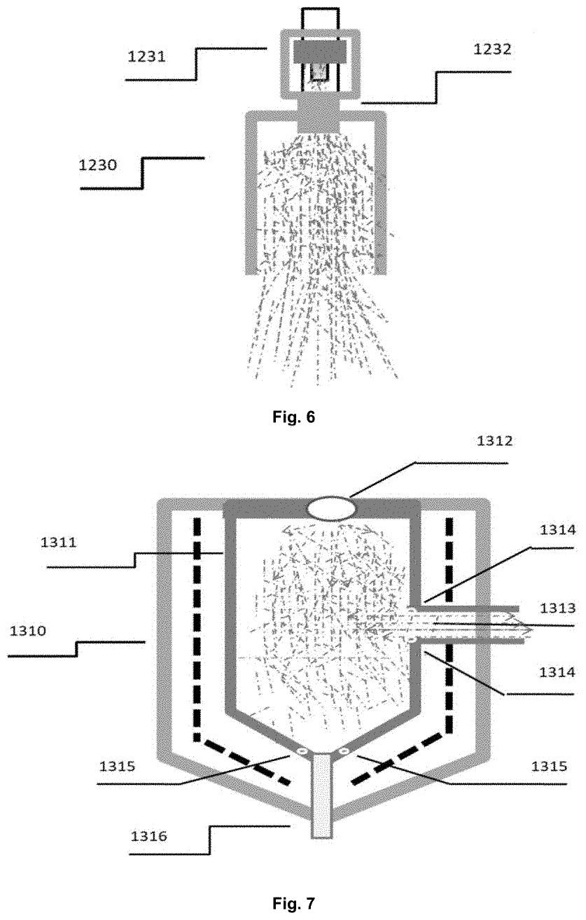

FIG. 6 schematically illustrates a third embodiment of a fragmentation device 1230. The third fragmentation device 1230 includes an atomization device 1231 and a vaporization device 1232. The atomization device 1231 and the vaporization device 1232 may be connected in series or integrated to form the third fragmentation device 1230.

FIG. 7 schematically illustrates an ionization chamber 1310 for generating ionized particles, according to some embodiments of the present disclosure. The ionization chamber 1310 includes a liner 1311, an inlet 1312, an outlet 1313, an ion selector 1314, a particle rotation-suspension setting 1315, and a discharge port 1316 for coarse particles. The particle rotation-suspension setting 1315 may have a plurality of inclined and straight gas holes. In some embodiments, the plurality of inclined and straight gas holes may form a substantially circular shape and are substantially evenly distributed at the bottom of the ionization chamber 1310. In some embodiments, the plurality of inclined and straight gas holes may be distributed in substantially alternate pattern. In some embodiments, the plurality of inclined and straight gas holes may be distributed such that one or more straight gas holes are followed by one or more inclined gas holes. In some embodiments, there may be a plurality of circular shapes or rings or strings of the plurality of inclined and straight gas holes formed at the bottom of the ionization chamber. In some embodiments, at least part of the plurality of inclined and straight gas holes form a matrix at the bottom of the ionization chamber. The holes are located, or the ring (or circular shape or irregular shape) is embedded, on the bottom of the ionization chamber. As used herein, the term “straight gas hole” refers to a gas hole through which a gas is injected into the ionization chamber in an upward fashion, such as, for example, substantially parallel to the central axis of the ionization chamber or the vertical side wall of the ionization chamber. As used herein, the term “inclined gas hole” refers to a gas hole through which a gas is injected into the ionization chamber at an angle (of, for example, at least 10, 15, 20, 25, 30, 40, 45, 50, 55, 60, 65, 70, 75, 80, or 85 degree) relative to the central axis of the ionization chamber, or lean towards the bottom surface of the ionization chamber more than the central axis of the ionization chamber, or at an angle (of, for example, no more than 1, 2, 3, 4, 5, 6, 7, 8, 9, 10, 12, 14, 16, 18, 20, or 25 degree) relative to the bottom surface of the ionization chamber. The gas from the inclined holes blows and sweeps along the inner wall of the liner of the ionization chamber so that the particles are rotated from bottom to top with the gas flow; the gas introduced by the straight holes flows upwards so that the larger particles, which fall to the bottom of the ionization chamber, jump up and down, and collide with each other to be broken up. The inlet 1312 of the ionization chamber 1311 is located on the top of the liner 1311; the outlet 1313 is located on the side of the liner 1311; the ion selector 1314 is embedded on the inner wall of the outlet 1313; the particle rotation-suspension setting 1315 is located or embedded around the discharge port 1316 for coarse particle; the discharge port 1316 for coarse particles is located on the bottom of the liner 1311.

The ion selector 1314 may be configured to allows ions of a certain size to pass through it (e.g., not more than about 500 nm for at least 85% of the ions that pass through the ion selector 1314).

In some embodiments, the particles distributed in the ionization chamber 1310 such that the smaller (and lighter) ions may mainly stay (or suspend) at the upper portion of the ionization chamber 1310 while the bigger (and heavier) ions may mainly stay (or suspend) at the lower portion of the ionization chamber 1310. In some embodiment, the ion selector 1314 applies a pressure differential between at least the bulk of the ionization chamber 1310 and the outlet 1313 around the entrance of the outlet 1313 such that ions with pre-determined particle sizes are allowed to pass through the ion selector 1314 and enter the outlet 1313. In some embodiments, the pressure differential and/or the location of the ion selector 1314 (e.g., there may be a plurality of outlet 1313 and its corresponding ion selector 1314 distributed vertically along the side wall of the ionization chamber 1310; or different ionization chamber 1310 may have different positions for the outlet 1313 and its corresponding ion selector 1314 relative to the bottom of the ionization chamber 1310) can be adjusted to allow different size range of the ions to pass through the ion selector 1314. In some embodiments, the ion selector may comprise a plurality of inclined gas holes whose orientation can inject inert gas along the passage of the outlet 1313 and away from the ionization chamber 1310. In some embodiments, the plurality of inclined holes may point away from the ionization chamber 1310. In some embodiments, the momentum caused by the injected inert gas through the plurality of inclined holes create the pressure differential such that ions of predetermined sizes may be pushed into the outlet 1313. In some embodiments, the plurality of holes may be connected with an inert gas source. In some embodiments, the ion selector 1314 is configured to select ions whose sizes are sizes are no more than about 1, 5, 10, 20, 30, 40, 50, 60, 70, 80, 90, 100, 150, 200, 250, 300, 350, 400, 450, or 500 nm. In some embodiments, for each of the selected range of ion sizes, the ions having the selected range of particle size are at least 50%, 55%, 60%, 65%, 70%, 75%, 80%, 85%, 90%, 95% of the particles that pass through the ion selector 1314.

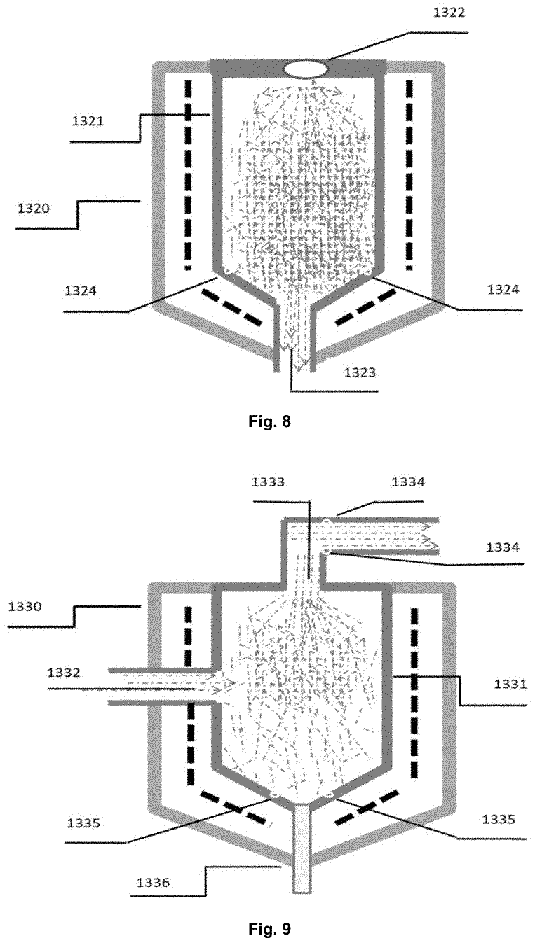

FIG. 8 schematically illustrates a second embodiment of an ionization chamber for generating ionized particles. The ionization chamber 1320 includes a liner 1321, an inlet 1322, an outlet 1323, and a particle rotation-suspension setting 1324. The inlet 1322 is located on the top of the liner 1321; the outlet 1323 is on the bottom of the liner 1321; and the particle rotation-suspension setting 1324 is located or embedded on the bottom of the liner 1321.

FIG. 9 schematically illustrates a third embodiment of an ionization chamber for generating ionized particles. The ionization chamber 1330 includes a liner 1331, an inlet 1332, an outlet 1333, a particle selector 1334, a particle rotation-suspension setting 1335, and a discharge port 1336 for coarse particles. The inlet 1332 is located on the side of the liner 1331; the outlet 1333 is located on the top of the liner 1331; the particle selector 1334 is embedded on the bend of the inner wall of the outlet 1333; the particle rotation-suspension setting 1335 is located or embedded around the discharge port 1336 for coarse particles; the discharge port 1336 for coarse particle is located on the bottom of the liner 1331.

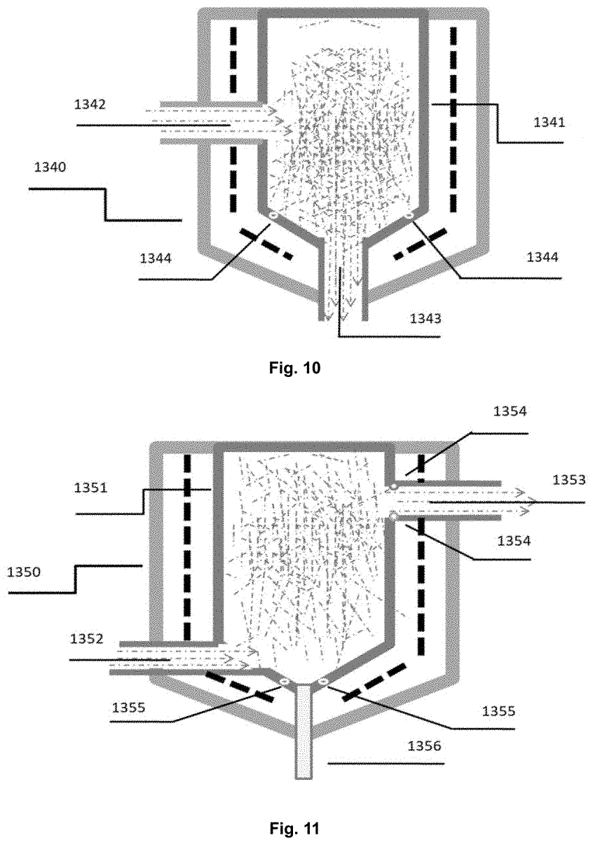

FIG. 10 schematically illustrates a fourth embodiment of an ionization chamber for generating ionized particles. The ionization chamber 1340 includes a liner 1341, an inlet 1342, an outlet 1343, and a particle rotation-suspension setting 1344. The inlet 1342 is located on the side of the liner 1341; the outlet 1343 is located on the bottom of the liner 1341; the particle rotation-suspension setting 1344 is located or embedded around the outlet 1343 on the bottom of the liner 1341.

FIG. 11 schematically illustrates a fifth embodiment of an ionization chamber for generating ionized particles. The ionization chamber 1350 includes a liner 1351, an inlet 1352, an outlet 1353, a particle selector 1354, a particle rotation-suspension setting 1355, and a discharge port 1356 for coarse particles. The inlet 1352 is located on one side of the liner 1351; the outlet 1353 is located on another side of the liner 1351; the particle selector 1354 is embedded on the inner wall of the outlet 1353; the particle rotation-suspension setting 1355 is located or embedded around the discharge port 1356 for coarse particle; the discharge port 1356 for coarse particle is located on the bottom of the liner 1351.

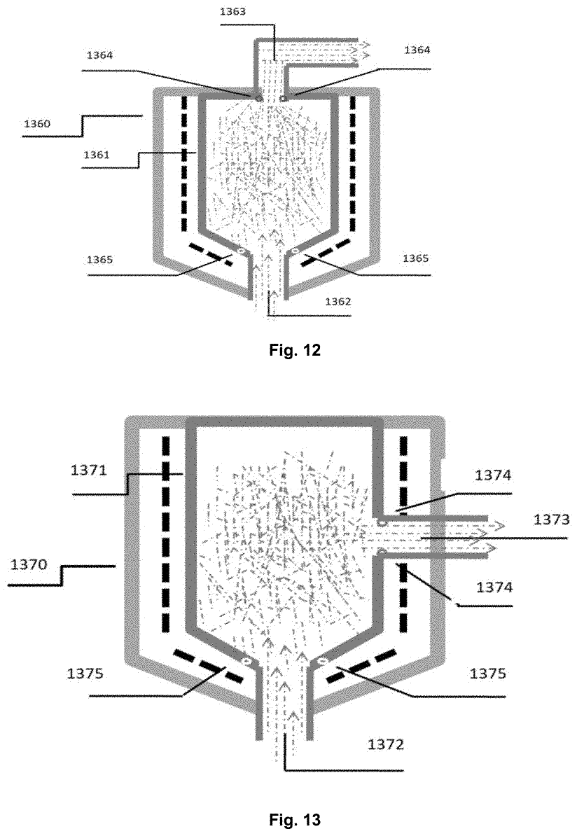

FIG. 12 schematically illustrates a sixth embodiment of an ionization chamber for generating ionized particles. The ionization chamber 1360 includes a liner 1361, an inlet 1362, an outlet 1363, a particle selector 1364, and a particle rotation-suspension setting 1365. The inlet 1362 is located on the bottom of the liner 1361; the outlet 1363 is located on the top of the liner 1361; the particle selector 1364 is located or embedded around the outlet 1363; the particle rotation-suspension setting 1365 is located or embedded around the inlet 1362.

FIG. 13 schematically illustrates a seventh embodiment of an ionization chamber for generating ionized particles. The ionization chamber 1370 includes a liner 1371, an inlet 1372, an outlet 1373, a particle selector 1374, and a particle rotation-suspension setting 1375. The inlet 1372 is located on the bottom of the liner 1371; the outlet 1373 is located on the side of the liner 1371; the particle selector 1374 is located or embedded around the outlet 1373; the particle rotation-suspension setting 1375 is located or embedded around the inlet 1372 on the bottom of the liner 1371.

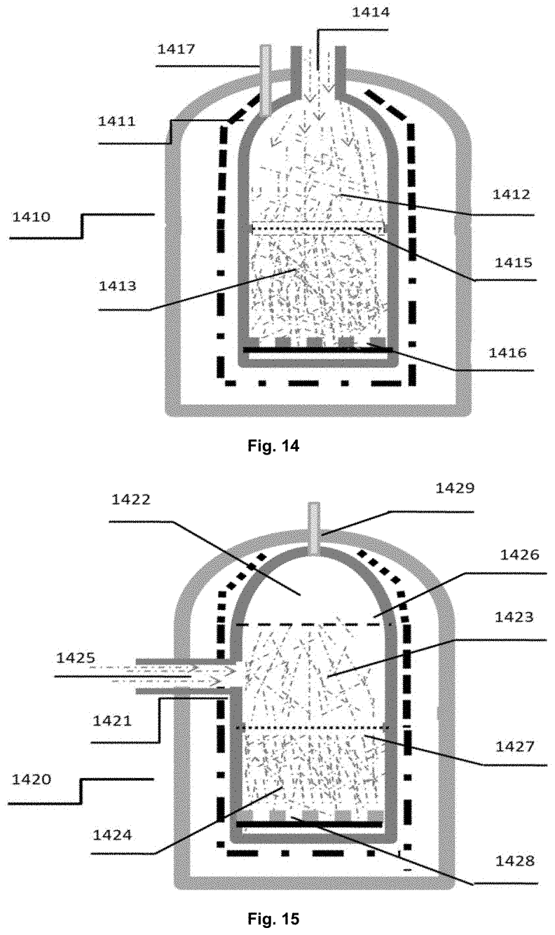

FIG. 14 schematically illustrates a growth chamber 1410 for producing block crystals of metal compounds, according to some embodiments of the present disclosure. The growth chamber 1410 includes a deposition-growth room 1411, an ion diffusion zone 1412, a crystal growth zone 1413, an inlet 1414 of deposition-growth room 1411, an isolation grid 1415, a deposition-growth groove 1416, and a discharge port 1417 for excess gas.

The deposition-growth room 1411 is divided into two zones, namely, the ion diffusion zone 1412 and the crystal growth zone 1413. The ion diffusion zone 1412 is located in the upper part of the deposition-growth room 1411; the crystal growth zone 1413 is located in the lower part of the deposition-growth room 1411; the inlet 1414 of the deposition-growth room is located on the top of the deposition-growth room 1411; the isolation grid 1415 is set between the ion diffusion zone 1412 and crystal growth zone 1413. The isolation grid 1415 can form a temperature difference between the ion diffusion zone 1412 and the crystal growth zone 1413 and allow uniform diffusion of particles.; the deposition-growth groove 1416 is located above the bottom of the deposition-growth room 1411; the discharge port 1417 for excess gas is located in the top of the deposition-growth chamber 1411.

FIG. 15 schematically illustrates a second embodiment of a growth chamber for producing block crystals of metal compounds. The growth chamber 1420 includes: a deposition-growth room 1421, an excess gas accumulation zone 1422, an ion diffusion zone 1423, a crystal growth zone 1424, an inlet 1425 of the deposition-growth room 1421, an isolation grid 1426 for excess gas, an isolation grid 1427, a deposition-growth groove 1428, and a discharge port 1429 for excess gas.

The deposition-growth room 1421 is divided into three zones, namely, the excess gas accumulation zone 1422, the ion diffusion zone 1423 and the crystal growth zone 1424. The excess gas accumulation zone 1422 is located in the upper part of the deposition-growth room 1421; the ion diffusion zone 1423 is located in the middle part of the deposition-growth room 1421; the crystal growth zone 1424 is located in the lower part of the deposition-growth room 1421. The inlet 1425 of the deposition-growth room is located in the middle part of the ion diffusion zone 1423 of the deposition-growth room 1421. The isolation grid 1426 for excess gas is set between the excess gas accumulation zone 1422 and the ion diffusion zone 1423; the isolation grid 1427 is set between the ion diffusion zone 1423 and the crystal growth zone 1424; the deposition-growth groove 1428 is located above the bottom of the deposition-growth room 1421; the discharge port 1429 for excess gas is located at the top of the deposition-growth room 1421.

The furnaces, fragmentation devices, ionization chambers, and growth chambers described above may be combined to form an apparatus for producing block crystals of a metal compound (e.g., gallium nitride).

### EMBODIMENT 1

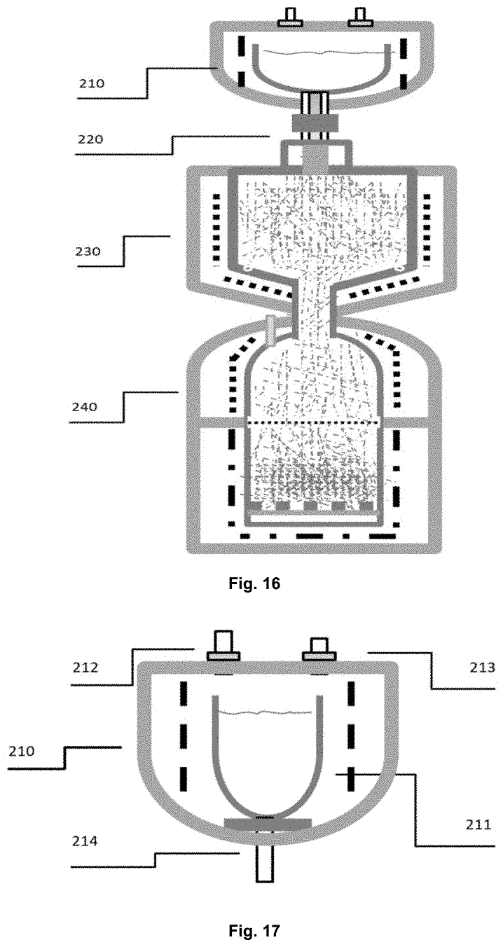

FIG. 16 schematically illustrates a vertical apparatus for producing block crystals of a compound (e.g., gallium nitride, aluminum nitride or silicon carbide), according to some embodiments of the present disclosure. The description of FIG. 16 will refer specifically to gallium nitride, but a person of ordinary skill will understand that other compounds can be formed using the apparatus. The apparatus of FIG. 16 includes a smelting furnace 210, a fragmentation device 220, an ionization chamber 230, and a growth chamber 240. The apparatus is a vertical structure; the smelting furnace 210 is above the fragmentation device 220, which is above the ionization chamber 230, which is above the growth chamber 240.

The gallium metal in smelting furnace 210 is vacuumed, heated, and liquefied to become a liquid metal, so that the gallium liquid metal automatically flows into or leads into the fragmentation device 220.

In the fragmentation device 220, gallium liquid metal undergoes multiple fragmentation (atomization and vaporization) treatments and gradually becomes fine and ultrafine gallium metal particles without the use of a solvent; then, the particles automatically enter or fall into the ionization chamber 230. Only particles that are below a certain size may enter the ionization chamber 230. Larger particles may remain suspended at and/or fall to the bottom of the fragmentation device 220 and be reused.

The temperature of the ionization chamber 230 may be set such that gallium nitride polycrystals do not form and the ultrafine gallium metal particles are made to be ionized completely. The fine and ultrafine gallium metal particles are fully mixed with nitrogen, stirred, and further heated to form a uniform distribution of gallium ions.

The gas (e.g., nitrogen or argon) is pumped into the ionization chamber 230 to mix and stir with the ionized gallium particles so that the particles are homogenized. The gas is made to rotate from bottom to top for blowing and sweeping the inner wall of the liner of the ionization chamber 230, so as to reduce the adhesion of the ionized gallium particles on the inner wall of the liner. At the same time, the ionized gallium particles which are driven by the gas collide with each other and become smaller so that more ionized gallium particles are generated; the aggregation and accumulation of the ionized gallium particles is thereby minimized.

The gallium ions are introduced into the growth chamber 240 and first enter the ion diffusion zone in the upper part of the growth chamber 240. Under the joint action of temperature difference, ion/particle concentration, and the reactive gas flow, the gallium ions pass through the isolation grid between the ion diffusion and crystal growth zones and enter the crystal growth zone in the lower part of the growth chamber 240 of gallium nitride. The temperature of the crystal growth zone is set in a range that is beneficial to the growth of gallium nitride crystals; the gallium ions are scattered and evenly distributed in the crystal growth zone. Finally, the gallium ions slowly fall and accumulate, react with a catalyst-free reactive gas (e.g., NH₃), and grow in the sedimentary grooves in the bottom of the growth chamber 240 to form gallium nitride block crystals with high thickness.

FIG. 17 schematically illustrates the smelting furnace 210 of the apparatus of FIG. 16, according to some embodiments of the present disclosure. The smelting furnace 210 includes a vacuum crucible/container 211, a vacuuming channel 212, a gas channel 213, and a diversion pipe 214. The smelting furnace 210 is sealed. The vacuuming channel 212 and gas channel 213 are located on the top of the smelting furnace 210; the vacuum crucible/container 211, which is open on the top, is located at the center on the bottom of smelting furnace 210; the diversion pipe 214 for liquid metal gallium is connected to the bottom of the vacuum crucible/container 211. The opposite end of the diversion pipe 214 is connected to the fragmentation device 220.

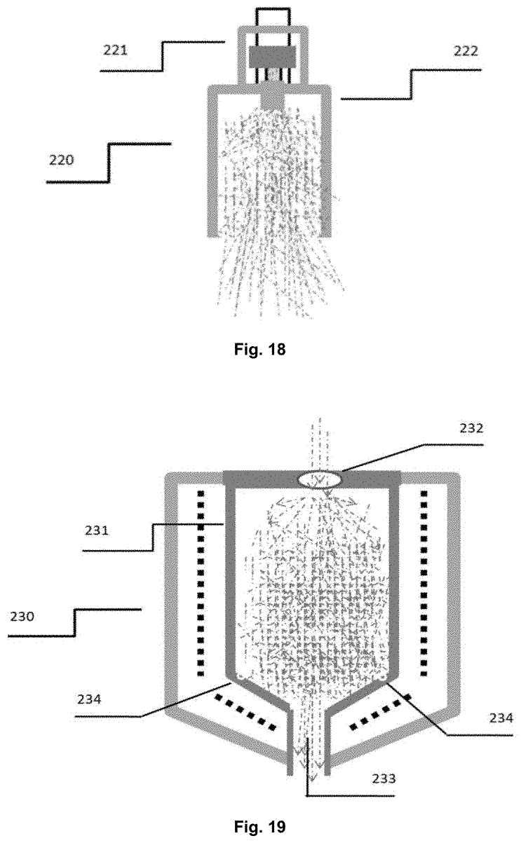

FIG. 18 schematically illustrates the fragmentation device 220 of the apparatus of FIG. 16, according to some embodiments of the present disclosure. The fragmentation device 220 includes: an atomization device 221 and a vaporization device 222. The atomization device 221 and the vaporization device 222 are connected in series or integrated together to form the fragmentation device 220 and embedded at the top of the ionization chamber 230.

FIG. 19 schematically illustrates the ionization chamber 230 of the apparatus of FIG. 16, according to some embodiments of the present disclosure. The ionization chamber 230 includes a liner 231, an inlet 232, an outlet 233, and a rotation-suspension setting 234. The inlet 232 is located at the top of the liner 231; the outlet 233 is located in the bottom of the liner 231; the rotation-suspension setting 234 is located or embedded at the corners on the bottom of the liner 231.

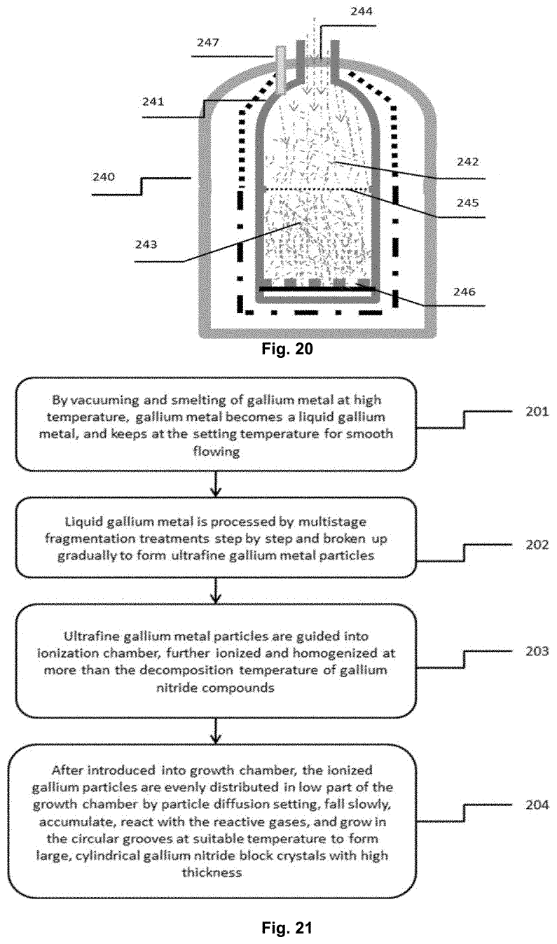

FIG. 20 schematically illustrates the growth chamber 240 of the apparatus of FIG. 16, according to some embodiments of the present disclosure. The growth chamber 240 includes: a deposition-growth room 241, a gallium ion diffusion zone 242, a growth zone 243, an inlet 244, an isolation grid 245, a deposition-growth groove 246, and a discharge port 247 for excess gas. The deposition-growth room 241 is divided into two zones, namely, the gallium ion diffusion zone 242 and the growth zone 243. The gallium ion diffusion zone 242 is located in the upper part of the deposition-growth room 241; the growth zone 243 is located in the lower part of the deposition-growth room 241; the inlet 244 is located at the top of the deposition-growth room 241; the isolation grid 245 is set between the gallium ion diffusion zone 242 and growth zone 243; the deposition-growth groove 246 of gallium nitride crystal is located above the bottom of the deposition-growth room 241; the discharge port 247 is located on the top of the deposition-growth chamber 241 of gallium nitride.

FIG. 21 is a flow chart of a process for producing gallium nitride block crystals, according to some embodiments of the present disclosure.

In an operation 201, pure metal gallium is placed in in the vacuum crucible/container 211. The pure metal gallium is vacuumed, heated, and liquefied at a temperature higher than 29.78° C. The liquid metal gallium is maintained at a specific temperature (higher than 29.78° C.) to maintain its fluidity; inert gas (helium, nitrogen or argon) is used to prevent the contamination of the pure metal gallium with external impurities.

In an operation 202, the liquid metal gallium metal flows through the diversion pipe 214 to form a narrow liquid flow. The liquid flow first enters the atomization device 221. The atomization device 221 generates micro sized gallium metal particles through high-frequency vibrations, ultrasonic waves, or high-pressure. Then, the micro sized gallium metal particles enter the vaporization device 222. The vaporization device 222 vaporizes the micro-sized gallium metal particles at a temperature of more than 4,000° C. The vaporization process may be solvent-free.

In an operation 203, the ultrafine gallium metal particles automatically fall into the liner 231 of ionization chamber. The temperature in the liner 231 is set at more than 1,300° C. so that gallium nitride polycrystals do not form and the ultrafine gallium metal particles are completely ionized.

A gas (e.g., nitrogen or argon) is then introduced through the rotation-suspension setting 234 to mix and stir with the ionized gallium particles so that the particles are homogenized. The gas is made to rotate from bottom to top for blowing and sweeping the inner wall of the liner 231, so as to reduce the adhesion of the ionized gallium particles to the inner wall of the liner 231. At the same time, the ionized gallium particles which are driven by the gas, collide with each other and become smaller. In this way, the aggregation and accumulation of the ionized gallium particles is reduced.

In an operation 204, the ionized gallium particles enter the gallium ion diffusion zone 242 in the upper portion of the deposition-growth room 241 through the inlet 244. The deposition-growth room 241 contains two zones: the gallium ion diffusion zone 242 and growth zone 243, in which the temperatures are adjusted and controlled in different time periods. A reactive gas (e.g., ammonia) is introduced into the growth zone 242. The deposition time of the gallium nitride is determined by the required thickness of the gallium nitride crystals.

Under the joint action of the temperature difference, ion/particle concentration, and the reactive gas flow, the ionized gallium particles pass through the isolation grid 245, diffuse uniformly, and enter the growth zone 243 in the lower part of the deposition-growth room 241. The diffusion rate of the ionized gallium particles is reduced; the particles are evenly distributed in the growth zone 243, which is located in the lower part of the deposition-growth room 241. Finally, the ionized gallium particles slowly fall and react with the catalyst-free reactive gas (e.g., nitrogen/N₂, ammonia/NH₃), and grow in the sedimentary grooves above the bottom of the deposition-growth room 241, which has a suitable temperature to form large cylindrical gallium nitride block crystals with high thickness.

The temperature in the gallium ion diffusion zone 242 is controlled and adjusted in different time periods: 1,200-1,300° C. during gallium ion introduction and crystal growth, and 800-1,200° C. while the excess gases (H₂ and N₂) are discharged.

The reaction temperature for gallium nitride in the growth zone 243 is set at: 900-1,200° C., wherein, the reaction equation is as follows:

2Ga+N₂=2GaN

2Ga+2NH₃=2GaN+3H₂

The superfluous gasses (hydrogen and nitrogen) rise automatically because of their own weight. They flow upward, pass through the isolation grid 245, and enter the gallium ion diffusion zone 242. After a period of time, the excess gases are discharged through the discharge port 247 in growth chamber on the top of the deposition-growth room 241.

### EMBODIMENT 2

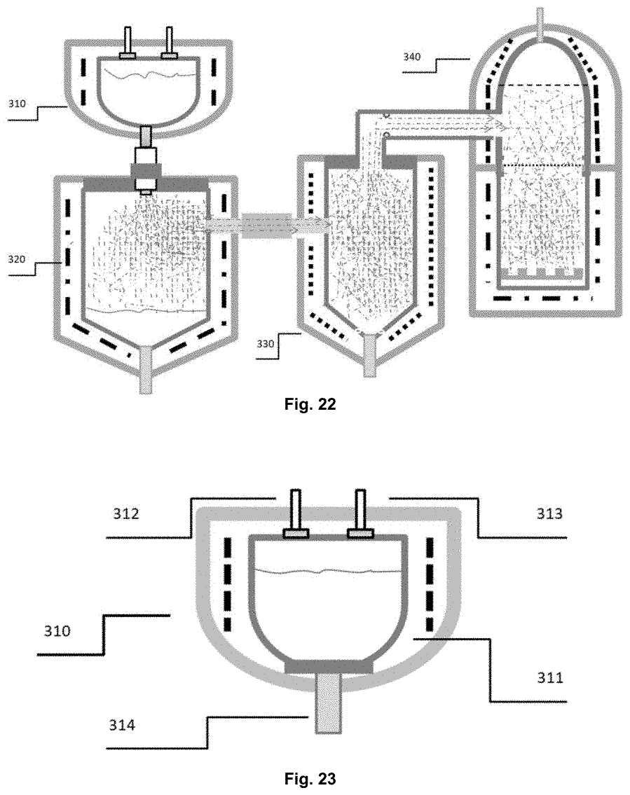

FIG. 22 schematically illustrates a horizontal apparatus for producing block crystals of a compound (e.g., gallium nitride, aluminum nitride or silicon carbide), according to some embodiments of the present disclosure. The description of FIG. 22 will refer specifically to silicon carbide, but a person of ordinary skill will understand that other compounds can be formed using the apparatus.

As shown in FIG. 22, the apparatus includes a smelting furnace 310, a fragmentation device 320, an ionization chamber 330, and a growth chamber 340. The apparatus of FIG. 22 is a vertical-horizontal mixing structure. The smelting furnace 310 is located above the fragmentation device 320; the ionization chamber 330 is located beside the fragmentation device 320; the growth chamber 340 is located beside the ionization chamber 330.

The silicon metal in the smelting furnace 310 is place under vacuum, heated, and liquefied to form a liquid metal, so that the silicon liquid metal automatically flows into the fragmentation device 320.

In the fragmentation device 320, the atomization device and the vaporization device are separately used to treat the silicon metal. The silicon liquid metal first undergoes atomization to form micro and micro-nanoscale silicon particles. The micro-nanoscale silicon particles are selected for the vaporization treatment to become ultrafine silicon metal particles; the larger micro-silicon particles are left to gather together for reuse. The ultrafine silicon metal particles are directed to the ionization chamber 330 through the vaporization device.

The temperature of the ionization chamber 330 is set above the decomposition temperature of silicon carbide so that silicon carbide polycrystals do not form and the ultrafine silicon metal particles are made to be ionized completely.

A gas (e.g., nitrogen) is introduced into the ionization chamber 330 to mix and stir with the ionized silicon particles so that the particles are homogenized. The gas is made to rotate from bottom to top for blowing and sweeping the inner wall of the liner of ionization chamber 330, so as to reduce the adhesion of the ionized silicon particles to the inner wall of the liner of ionization chamber 330. At the same time, the ionized silicon particles, which are driven by the gas, collide with each other and become smaller so that additional smaller ionized silicon particles are generated; the aggregation and accumulation of the ionized silicon particles is thereby reduced.

Through the particle selecting-orienting setting on the top of the ionization chamber 330, the ionized silicon particles are directed into the growth chamber 340. First, the particles are guided to enter the ion diffusion zone in the middle part of the growth chamber 340 and diffuse uniformly. Under the joint action of temperature difference, ion/particle concentration, and the reactive gas flow, the ionized silicon particles fall and pass through the isolation grid between the ion diffusion and crystal growth zones and enter the crystal growth zone in the lower part of the growth chamber 340. The temperature in the crystal growth zone is set so as to be beneficial to the growth of silicon carbide crystals. After the ionized silicon particles pass through the isolation grid between the ion diffusion and crystal growth zones, they spread around the crystal growth zone in the lower part of the growth chamber 340, slowly fall, accumulate, and react with the catalyst-free reactive gas, and grow at suitable temperature in the sedimentary grooves above the bottom of the growth chamber 340 to form large, high purity silicon carbide block crystals with high thickness.

FIG. 23 schematically illustrates of the smelting furnace 310 of the apparatus of FIG. 22, according to some embodiments of the present disclosure. The smelting furnace 310 includes: a vacuum crucible/container 311, a vacuuming channel 312, a gas channel 313, and a diversion pipe 314 liquid. The vacuuming channel 312 and the gas channel 313 are located on the top of the vacuum crucible/container 311. The vacuuming channel 312 can remove air from the vacuum crucible/container 311 so as to generate a vacuum. The gas channel 313 can introduce a non-reactive gas into the vacuum crucible/container 311. One end of the diversion pipe 314 is connected to the bottom of the vacuum crucible/container 311, and the other end is directly connected to the fragmentation device 320.

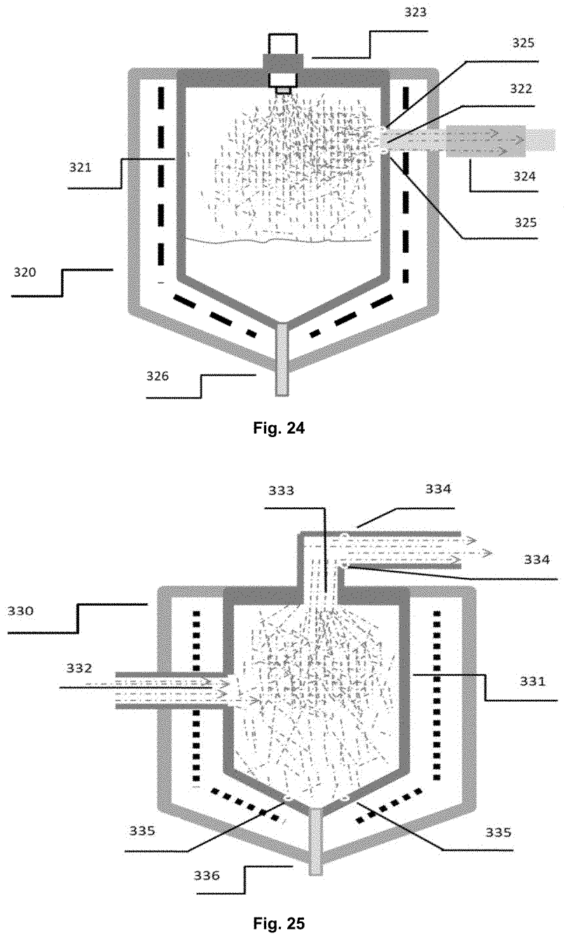

FIG. 24 schematically illustrates the fragmentation device 320 of the apparatus of FIG. 22, according to some embodiments of the present disclosure. The fragmentation device 320 includes: a collection tank 321, an outlet 322 for micro-nano sized silicon particles, an atomization device 323, a vaporization device 324, a particle selector 325, and a discharge port 326. Through the diversion pipe 314, the top of the collection tank 321 is connected to the bottom of the vacuum crucible/container 311. The outlet 322 for micro-nano sized silicon particles is located on the side of the collection tank 321. The atomization device 323 and vaporization device 324 are separately located. The atomization device 323 is embedded at the top of the collection tank 321; the vaporization device 324 is connected to the outlet 322 for micro-nano sized silicon particles; the particle selector 325 is embedded on the inner wall of the outlet 322 of micro-nano sized silicon particles; the discharge port 326 is located at the bottom of the collection tank 321.

FIG. 25 schematically illustrates the ionization chamber 330 of the apparatus of FIG. 22, according to some embodiments of the present disclosure. The ionization chamber 330 includes: a liner 331, an inlet 332, an outlet 333, a particle selector 334, a particle rotation-suspension setting 335, and a discharge port 336 for coarse particles. The inlet 332 is located in the middle part of the liner 331; the outlet 333 located on the top of the liner 331; the particle selector 334 is composed of multiple oblique holes, which are evenly distributed and formed into a ring and located above the outlet 333. The oblique holes are embedded in the inner wall of the corners of the channel between the ionization chamber 330 and the growth chamber 340. The particle rotation-suspension setting 335 is made up of a number of oblique holes and straight holes, which are evenly distributed to form a ring and embedded on the bottom of the liner 331 and around the discharge port 336; the discharge port 336 is located at the center of the bottom of the liner 331.

FIG. 26 schematically illustrates the growth chamber 340 of the apparatus of FIG. 22, according to some embodiments of the present disclosure. The growth chamber 340 includes: a deposition-growth room 341, an excess gas accumulation zone 342, a silicon ion diffusion zone 343, a growth zone 344, an inlet 345, an isolation grid 346, an isolation grid 347, a deposition-growth groove 348, and a discharge port 349 for excess gas. The deposition-growth room 341 is divided into three zones, namely, the excess gas accumulation zone 342, the silicon ion diffusion zone 343, and the growth zone 344. The excess gas accumulation zone 342 is located in the upper part of the deposition-growth room 341; the silicon ion diffusion zone 343 is located in the middle of the deposition-growth room 341; the growth zone 344 is located in the lower part of the deposition-growth room 341. The inlet 345 is located in the silicon ion diffusion zone 343. The isolation grid 346 is set between the excess gas accumulation zone 342 and the silicon ion diffusion zone 343; the isolation grid 347 is set between the silicon ion diffusion zone 343 and the growth zone 344; the deposition-growth groove 348 is located in the bottom of the deposition-growth room 341; the discharge port 349 of excess gas in growth chamber of silicon carbon is located at the top of the deposition-growth room 341.

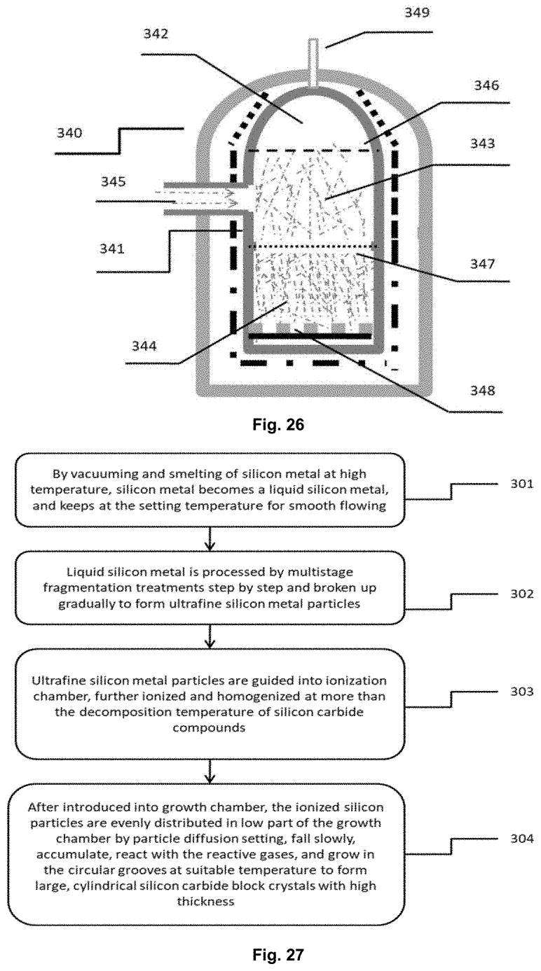

FIG. 27 is a flow chart of a process for producing silicon carbide block crystals, according to some embodiments of the present disclosure.

In operation 301, pure metal silicon is introduced into the vacuum crucible/container 311 and placed under vacuum, heated, and liquefied at a temperature of 1,410° C. or higher. The liquid metal silicon is maintained at a specific temperature (higher than 1,410° C.) to maintain better fluidity; inert gas (e.g., helium, nitrogen or argon) is used to protect the silicon from contamination with external impurities.

In an operation 302, the liquid metal silicon is atomized and vaporized in separate steps. The liquid metal silicon enters atomization device 323 for atomization, resulting in micro and micro-nanoscale silicon particles. The particle selector 325 allows particles that are a sufficiently small size to enter the vaporization device 324, which vaporizes the particles at a temperature of more than 4,000° C. to become ultrafine silicon metal particles; the larger silicon particles are left to fall to the bottom of the collection tank 321, gather together, and be collected through discharge port 326 for reuse. With the vaporization device 324, the ultrafine silicon metal particles are automatically directed towards the inlet 332 of ionization chamber.

In an operation 303, the ultrafine silicon metal particles enter the liner 331 of the ionization chamber. The temperature in the liner 331 is set at more than 2,600° C. so that silicon carbon polycrystals do not form and the ultrafine silicon metal particles are made to be ionized completely.

The heavier particles fall to the bottom of the liner 331 of the ionization chamber. An inert gas (e.g., helium, nitrogen or argon), which is introduced from the particle rotation-suspension setting 335, makes the heavier silicon particles rotate, blow, and sweep along the inner wall of the liner 331 of ionization chamber, so as to reduce the adhesion of the ionized silicon particles to the inner wall of the liner 331. Meanwhile, the ionized silicon particles which are driven by the gas, collide with each other and become smaller. In this way, the aggregation and accumulation of the ionized silicon particles is also reduced.

The ionized silicon particles are introduced into the deposition-growth room 341 through the outlet 333. The particle selector 334 only allows particles of a sufficiently small size to enter the deposition-growth room 341. After a considerable period of time, the larger silicon particles, which cannot enter the deposition-growth room 341 due to their own weight are left on bottom of the liner 331 of ionization chamber and are discharged through the discharge port 336.

In an operation 304, the ionized silicon particles are guided into the silicon ion diffusion zone 343 in the middle part of the deposition-growth room 341. The deposition-growth room 341 contains three regions: the excess gas accumulation zone 342, the silicon ion diffusion zone 343, and growth zone 344, in which the temperatures are adjusted and controlled in different time periods. The deposition-growth time of silicon carbide is determined by the thickness of the required silicon carbide crystal.

Under the joint action of temperature difference, ion/particle concentration, and the reactive gas flow, the ionized silicon particles diffuse through the isolation grid 347 and enter the growth zone 344 in the lower part of the deposition-growth room 341. The ionized silicon particles are evenly distributed in the growth zone 344 in the lower part of the deposition-growth room 341. Finally, the ionized silicon particles fall, accumulate, react with the catalyst-free reactive gas (CH₄), and grow in the circular deposition-growth groove 348 under suitable temperature to form large, high purity cylindrical silicon carbide block crystals.

The temperature of the excess gas accumulation zone 342 is controlled and adjusted in different time periods: more than 2,500° C. during the introduction of silicon ion and crystal growth, and 1,600-2,100° C. while the excess gases (H₂ and N₂) are discharged. During the introduction of silicon ions and crystal growth, the excess gas accumulation zone 342 maintains a higher temperature for a higher temperature difference or gradient to growth zone so that ions are forced to diffuse into the growth zone. Otherwise, ions go up into the excess gas accumulation zone. After the period of crystal growth finishes, the excess gases (H₂ and N₂) are required to be discharged, the temperature of excess gas accumulation zone decreases so that the lighter gases go up for discharging. The temperature in the silicon ion diffusion zone 343 is controlled and adjusted as follows: 2,300-2,600° C. during introduction of silicon ion and crystal growth; 1,600-2,100° C. while the excess gases (H₂ and N₂) are discharged.

The reaction temperature for silicon carbide in the growth zone 344 is set at: 1,800-2,500° C.; wherein, the reaction equation is as follows:

Si+CH₄=SiC+2H₂

The remainder or superfluous gasses (H₂ and N₂) rise automatically because of their lighter weight. They flow upward through the isolation grid 347 and the isolation grid 346 and enter the excess gas accumulation zone 342. After a period of time, the remainder or superfluous gasses are discharged through the discharge port 349 on the top of deposition-growth room 341.

### Conclusion

The methods and devices described herein can be easily modified for the production of different compound block crystals, such as nitrogen, oxygen, and carbon-based compounds, by switching the employed source metals and reactive gases. In addition, the main characteristics of this method are: using physical means (e.g., mechanical force/energy) under the combined action of heat energy, kinetic energy and reaction time, to form metal compound bulk crystals without solvents and catalysts. Additional characteristics of this method are: using high-pressure gas (e.g., helium, nitrogen or argon) to break the liquid flow into particles of the source metal; optionally applying ultrasonic waves and/or mechanically vibrating the liquid flow to further breaking the liquid flow or bigger particles of the source metal without using a solvent or chemical means. Still additional characteristics of the this method are: inserting a particle selector between the atomization device and the vaporization device such that particles of predetermined sizes may be conveyed to the ionization chamber from the fragmentation device; and inserting an ion selector between the ionization chamber and the growth chamber such that ions of predetermined sizes may be conveyed to the growth chamber from the ionization chamber. Additional characteristics of the this method are: inclined holes (e.g., for the particle selector, the ion selector and the rotation-suspension setting) are used to inject inert gases along the inner walls of the device, chamber, or outlet(s), etc., such that to prevent or reduce deposition or aggregation of particles or ions, or adhesion of the particles or ions to the device, chamber, or outlet(s), respectively.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A method for forming block crystals of a metal compound, comprising:
(a) introducing a source metal into a furnace;
(b) forming a complete or partial vacuum in said furnace and increasing a temperature of said furnace above a melting point of said source metal to form a liquid flow of said source metal;
(c) breaking said liquid flow to generate particles of said source metal;
(d) ionizing said particles in an ionization chamber to form ionized particles, wherein a temperature of said ionization chamber is above a decomposition temperature of said metal compound; and
(e) introducing said ionized particles into a growth chamber comprising a reactive gas that is reactive with said ionized particles, thereby forming said block crystals of said metal compound.

2. The method of claim 1, wherein:
(i) (c) comprises one or more of (1) applying a high-pressure gas to said liquid flow, (2) applying ultrasonic waves to said liquid flow, or (3) mechanically vibrating said liquid flow; or
(ii) (c) comprises (1) applying a high-pressure gas to said liquid flow, and (2) applying ultrasonic; or
(iii) (c) comprises (1) applying a high-pressure gas to said liquid flow, and (2) mechanically vibrating said liquid flow; or
(iv) (c) comprises (1) applying a high-pressure gas to said liquid flow, (2) applying ultrasonic waves to said liquid flow, and (3) mechanically vibrating said liquid flow.

3. The method of any one of claim 1, wherein:
(i) (d) comprises introducing a flow of inert gas into said ionization chamber, thereby preventing (1) aggregation of said ionized particles and (2) adhesion of said ionized particles to said ionization chamber; or
(ii) (b) comprises, subsequent to forming said complete or partial vacuum in said furnace, introducing another inert gas into said furnace; or
(iii) subsequent to (c), removing a subset of said particles that are larger than a threshold size before reaching said ionization chamber; or
(iv) (c) comprises atomizing and vaporizing said liquid flow; or
(v) (c) is performed without a solvent.

4. The method of claim 3, wherein:
(i) each of said high-pressure gas, said inert gas and said another inert gas is independently helium, nitrogen or argon; or
(ii) said subset of said particles are reused.

5. The method of claim 1, wherein:
(i) said ionized particles diffuse from said ionization chamber to said growth chamber along a concentration gradient or a temperature gradient; or
(ii) said block crystals of said metal compound form in a sedimentary groove in a bottom of said growth chamber; or
(iii) a temperature of said growth chamber facilitates growth of said block crystals of said metal compound; or
(iv) said reactive gas is catalyst-free; or
(v) said source metal is gallium, aluminum, indium, silicon, or a combination thereof.

6. The method claim 1, wherein:
(i) said source metal is a pure metal; or
(ii) said source metal is a combination of metals.

7. The method of claim 6, wherein (b) comprises increasing said temperature of said furnace above a melting point of a metal with a highest melting point in said combination of metals.

8. The method of claim 1, wherein:
(i) said source metal is gallium, wherein said reactive gas is nitrogen or ammonia, and wherein said metal compound is gallium nitride; or
(ii) said source metal is aluminum, wherein said reactive gas is nitrogen or ammonia, and wherein said metal compound is aluminum nitride; or
(iii) said source metal is silicon, wherein said reactive gas is methane, and wherein said metal compound is silicon carbide; or
(iv) said source metal is indium, wherein said reactive gas is nitrogen or ammonia, and wherein said metal compound is indium nitride.

9. An apparatus for forming block crystals of a metal compound, comprising:
a furnace configured to heat a source metal to form a liquid flow of said source metal;
a fragmentation device coupled to said furnace, wherein said fragmentation device is configured to generate particles of said source metal from said liquid flow;
an ionization chamber coupled to said fragmentation device, wherein said ionization chamber is configured to ionize said particles to form ionized particles; and
a growth chamber coupled to said ionization chamber, wherein said growth chamber is configured to facilitate growth of said block crystals of said metal compound through a reaction between said ionized particles and a reactive gas in said growth chamber.

10. The apparatus of claim 9, wherein:
(i) said fragmentation device comprises one or more atomization devices and a vaporization device.
(ii) said one or more atomization devices comprise a gas atomizer, a mechanical vibrator, or an ultrasonic atomizer; or
(iii) said fragmentation device comprises one or more atomization devices and a vaporization device; and wherein said apparatus further comprises a particle selector disposed between said one or more atomization devices and said vaporization device; or
(iv) said apparatus further comprises an ion selector disposed between said ionization chamber and said growth chamber; or
(v) said ionization chamber comprises a particle rotation-suspension setting disposed on a bottom portion of said ionization chamber, wherein said particle rotation-suspension setting is configured to generate a plurality of upward inert gas flows introduced by a plurality of straight holes and a plurality of inclined inert gas flows introduced by a third plurality of inclined holes.

11. The apparatus of claim 10, wherein:
(i) said particle selector comprises a first plurality of inclined gas holes; or
(ii) said one or more atomization devices comprise a gas atomizer, a mechanical vibrator, or an ultrasonic atomize; or
(iii) said ion selector comprises a second plurality of inclined gas holes; or
(iv) said plurality straight holes and said third plurality of inclined holes (1) are distributed substantially in a circular shape or an irregularly shape, (2) are crossed with each other or in substantially alternate pattern, or (3) are substantially evenly distributed at said bottom of said ion chamber.

12. The apparatus of claim 9, wherein said furnace comprises a crucible configured to hold said source metal.

13. The apparatus of claim 9, wherein:
(i) said crucible is sealed; or
(ii) said crucible is open to said furnace; or
(iii) said furnace comprises a vacuuming channel configured to remove air from said crucible or said furnace, or both, to form a full or partial vacuum in said crucible or said furnace; or
(iv) said furnace comprises a gas channel configured to supply an inert gas to said crucible or said furnace, or both; or
(v) said vacuuming channel or said gas channel are disposed in a top portion of said crucible or a top portion of said furnace.

14. The apparatus of 1, wherein:
(i) further comprising a diversion channel that couples said furnace to said fragmentation device; or
(ii) said one or more atomization devices and said vaporization device are connected in series or integrated together; or
(iii) said one or more atomization devices are a plurality of atomization devices, and wherein said plurality of atomization devices are connected in series or integrated together; or
(iv) said vaporization device comprises an induction heater, direct current arc, a plasma source, a microwave source, or a laser; or
(v) said growth chamber comprises a deposition-growth room; or
(vi) said fragmentation device is coupled to a bottom portion of said furnace, wherein said ionization chamber is coupled to a side of said fragmentation device, and wherein said growth chamber is coupled to a top of said ionization chamber; or
(vii) said ionization chamber comprises a discharge port for coarse particles, wherein said discharge port is disposed in a bottom portion of said ionization chamber.

15. The apparatus of claim 14, wherein said deposition-growth room comprises a top ion diffusion zone, a bottom growth zone, and an isolation grid disposed between said ion diffusion zone and said growth zone.

16. The apparatus of claim 15, said isolation grid comprises a plurality of holes that allow diffusion of said ionized particles.

17. The apparatus of claim 15, wherein said bottom growth zone comprises circular sedimentary grooves for growing said block crystals of said metal compound.

18. The apparatus of claim 9, wherein said growth chamber comprises a deposition-growth room, wherein said deposition-growth room comprises a top gas accumulation zone, a middle ion diffusion zone, a bottom growth zone, a first isolation grid disposed between said middle ion diffusion zone and said bottom growth zone, and a second isolation grid disposed between said top gas accumulation zone and said middle ion diffusion zone.

19. The apparatus of claim 18, wherein an entrance to said deposition-growth room is in said middle ion diffusion zone.

20. The apparatus of claim 18, wherein said top gas accumulation zone comprises an excess gas discharge port.
